(19) United States
(12) Patent Application Publication
(10) Pub. No.: US 2003/0033576 A1
(43) Pub. Date: Feb. 13, 2003

(54) Functional pathway configuration at a system/IC interface

(76) Inventors: Mark Palmer, Phoenix, AZ (US); Steven Eric Schlanger, Flagstaff, AZ (US)

Correspondence Address: BAKER BOTTS, LLP, 910 LOUISIANA, HOUSTON, TX, 77002-4995, US

(21) Appl. No.: 09/866,236

(22) Filed: May 25, 2001

(51) Int. Cl. G06F 7/38; H03K 19/173; G06F 17/50

(52) U.S. Cl. 716/1; 326/37

(57) ABSTRACT

The present invention relates generally to functional pathway configurations at the interfaces between integrated circuits (ICs) and the circuit assemblies with which the ICs communicate. More particularly, the present invention relates generally to the functional pathway configuration at the interface between a semiconductor device (e.g., computer chips like microcontrollers, microprocessors, application specific integrated circuits (ASIC), programmable gate arrays (PGA) and other devices and/or combinations thereof) and the circuitry of a system including the chip. Even more particularly, the present invention relates to an IC functional pathway configuration for the interface between the IC and a system in which the IC is embedded to support infrared communications.

### FIELD OF THE INVENTION

The present invention relates generally to functional pathway configurations at the interfaces between integrated circuits (ICs) and the circuit assemblies with which the ICs communicate. More particularly, the present invention relates generally to the functional pathway configuration at the interface between a semiconductor chip including an IC (e.g., computer chips like microcontrollers, microprocessors, application specific integrated circuits (ASIC), programmable gate arrays (PGA) and other devices and/or combinations thereof) and the circuitry of a system including the chip. Even more particularly, the present invention relates to 18-pin and 20-pin microcontroller functional pathway configurations for the interface between the microcontroller and a system in which the microcontroller is embedded to support infrared communications. Advantageously, the microcontroller comprises an infrared encoder/decoder disposed between an IC controller including a UART and an IrDA optical transceiver.

### BACKGROUND OF THE INVENTION

The electronics industry is generally divided into two main segments: application products companies and semiconductor companies. The application products companies segment includes the companies that design, manufacture, and sell the wide variety of semiconductor-based goods. The semiconductor companies segment includes integrated circuit (IC) design companies (i.e., fabless companies which may design and/or sell semiconductor chips), foundries (i.e., companies that manufacture chips for others), and partially or fully integrated companies that may design, manufacture, package and/or market chips to application products companies.

There is a large range of semiconductor-based goods available across a broad spectrum of applications, i.e., goods which include one or more semiconductor devices, in applications ranging from manufactured printed circuit boards to consumer electronic devices (stereos, computers, toasters, microwave ovens, etc.) and automobiles (which, for example, include semiconductor devices in fuel injection, anti-lock brake, power windows and other on-board systems). Thus, as one might imagine, there also are a wide variety of semiconductor devices available to meet the various requirements of such products and applications.

Perhaps the two most familiar types of semiconductor devices today are microcontroller and microprocessor computer chips. Microcontrollers, which are the “brains” of a broad range of consumer and industrial applications, differ from microprocessors primarily from the standpoint of the end-user consumer. Typically, consumers concern themselves with the type of microprocessor in a product because the consumers will perceive different performance characteristics or results depending upon the type of microprocessor a product uses (e.g., personal computer applications). Microcontrollers, on the other hand, typically are embedded in an application system and do not enter into the equation when end-user consumers are making purchasing decisions.

Typically, semiconductor companies who offer microcontrollers to products companies provide the microcontroller with a set of features and capabilities appropriate for a particular product or application. Thus, microcontrollers may have a broad range of features and capabilities, and semiconductor companies typically tend to offer their customers a wide range of microcontroller products to meet their customers' needs. For example, a semiconductor company may offer a family of products including a feature-rich “high-end” product (e.g., for automobile applications) and one or more “low-end” products including fewer features (e.g., for household appliance applications).

But while an end-user consumer, concerned only with whether a product works, might be indifferent as to the microcontroller device included in a product, the product designer and manufacturer certainly are not. Product companies generally will expend great efforts to ensure that their products work properly and that consumers receive value and remain satisfied. Thus, product companies tend to select microcontrollers for use in an application based on their features and capabilities, not to mention costs and other factors.

In view of such circumstances, there tends to be vigorous competition amongst semiconductor companies for microcontroller “design wins.” In other words, at the design stage, when a products company is designing a product for a given application, semiconductor companies compete for having their microcontroller included in the product. Once a product company establishes a design and sets the functional pathway configuration for the interface between a microcontroller and the system in which the microcontroller is embedded, the product company is less likely to change the configuration to accommodate another microcontroller having a different functional pathway configuration. Such configuration changes typically result in increased costs for the product company due to the system in which the microcontroller is embedded having to be re-designed.

While there are a number of factors involved in any decision to award a design win, one such factor comprises a semiconductor company's product “roadmap.” Over time, end-user consumers generally tend to favor future generation consumer products having increased features at lower costs. Accordingly, product companies evaluating microcontroller products of two or more semiconductor companies today will consider whether the particular solutions being offered now will allow them to migrate easily from a basic first generation microcontroller to an enhanced future generation microcontroller having increased capabilities and features. Such migration—without the products company incurring extensive system re-design costs—in general is necessary if the products company is to offer the future generation products that consumers typically demand.

Accordingly, there remains a need for a simple and convenient functional pathway configuration for the interface between a microcontroller and the system in which the microcontroller is embedded, e.g., that tends to promote increased performance with lower costs.

### SUMMARY OF THE INVENTION

The present invention may address one or more of the problems set forth above. Certain possible aspects of the present invention are set forth below as examples. It should be understood that such aspects are presented simply to provide the reader with a brief summary of certain forms the invention might take, and that these aspects are not intended to limit the scope of the invention. Indeed, the invention may encompass a variety of aspects that may not be set forth below.

In one embodiment of the present invention, a functional pathway configuration at the interface between an integrated circuit (IC) and the circuit assembly with which the IC communicates is provided. In a further embodiment, a functional pathway configuration at the interface between a semiconductor chip including an IC (e.g., computer chips like microcontrollers, microprocessors, application specific integrated circuits (ASIC), programmable gate arrays (PGA) and other devices and/or combinations thereof) and the circuitry of a system including the chip is provided.

In general, IR communication is a wireless, two-way data connection that uses infrared light. The infrared light may be generated, for example, by transceiver signaling technology. IrDA is an open standard for infrared communication. IrDA 1.0 specifies a maximum communication speed of 115 k bps and IrDA 1.1 specifies a maximum communication speed of 4 MHz. The Infrared Data Association (IrDA) is an organization which promotes an IR standard for interoperability of wireless IR links between various manufacturers devices. The IrDA defines a set of specifications, or protocol stack, that provides for the establishment and maintenance of an IR link so that error free communication is possible.

In accordance with the present invention, in one embodiment a system including the IC may comprise an IR encoder/decoder disposed between an IrDA optical transceiver (e.g., the HSDL-1001, available from Agilent Technologies, Inc.) and a controller (e.g., computer chips like microcontrollers, microprocessors, application specific integrated circuits (ASIC), programmable gate arrays (PGA) and other devices and/or combinations thereof) including a UART. Typically, the IR encoder/decoder receives data from the controller UART, encodes or modulates the data, and outputs electrical pulses to the transceiver. The IR encoder/decoder also receives electrical pulses from the IR transceiver, decodes or demodulates the pulses, and transmits data to the controller UART. Thus, in still a further embodiment, a microcontroller functional pathway configuration is provided for the interface between the microcontroller and a system in which the microcontroller is embedded to support infrared (IR) communications.

In one aspect, the present invention comprises an integrated circuit (IC) including a plurality of connections or “pins.” Advantageously, at least one pin comprises a power connection, at least one pin comprises a ground connection, and the remaining pins are input, output or input/output (I/O) connections, wherein each pin may have one or more associated functions. The pins may be analog, digital, or mixed-signal (can be analog or digital). Some pins advantageously are multiplexed with one or more alternate functions for the peripheral features on the microcontroller so that in general when a peripheral is enabled that particular pin may not be used, for example, as a general purpose I/O pin.

In one embodiment, an integrated circuit (IC) in accordance with the present invention advantageously includes up eighteen connections or pins. Each pin may be adapted and described according to the function(s) dedicated to the connection, so that all or a portion of the connections together define a functional pathway configuration at the interface between the microcontroller and the system in which the microcontroller may be embedded. Alternately, in another embodiment, the present invention comprises a system for receiving such an IC.

In yet another embodiment, an integrated circuit (IC) in accordance with the present invention advantageously includes up to twenty connections or pins. Each pin may be adapted and described according to the function(s) dedicated to the connection, so that all or a portion of the connections together define a functional pathway configuration at the interface between the microcontroller and the system in which the microcontroller may be embedded. Alternately, in still another embodiment, the present invention comprises a system for receiving such an IC.

In accordance with the present invention, and depending upon the particular application involved, the IC with which a system interfaces may comprise a packaged IC. Examples of types of packaging include a dual in-line package (DIP), which may comprise molded plastic dual in-line package (PDIP) or ceramic dual in-line package (CERDIP); shrink small outline package (SSOP); micro lead frame (MLF); pin grid arrays (PGAs); ball grid arrays (BGAs); quad packages; thin packages, such as flat packs (FPs), thin small outline packages (TSOPs), small outline IC (SOIC) or ultrathin packages (UTPs); lead on chip (LOC) packages; chip on board (COB) packages, in which the chip is bonded directly to a printed-circuit board (PCB); and others. However, for the sake of clarity and convenience only, and without limitation as to the scope of the present invention, reference will be made herein primarily to PDIP or CERDIP ICs.

Tables 1 and 2 describe exemplary embodiments including the various functions that the IC may perform, with the functions arranged by pin dedication. Of course the exact pin and function names used in any particular embodiment or application may vary depending upon the naming convention(s) selected. Table 1 is directed to an exemplary embodiment having Data Terminal Equipment (DTE) functionality. Table 2 is directed to another exemplary embodiment having Data Communication Equipment (DCE) functionality. The embodiments described in Tables 1 and 2 in general may be suited for applications involving devices having IR ports allowing for short range wireless connection to other IR-enabled devices. Examples of such applications include consumer products, such as digital cameras and camcorders; computers and peripheral products, such as notebook and desktop PCs, handheld PCs/PDAs/organizers, printers and adapters; telecommunication products, such as cellular phones, pagers, and wireless LANs; industrial applications, such as application specific PCs and peripherals, and retail devices; and automotive applications, such as those involving fleet management.

TABLE 1
(DTE)

| PIN | PIN | BUFFER | |
|---|---|---|---|
| NAME | TYPE | TYPE | DESCRIPTION |
| BAUD0 | I | ST | BAUD1:BAUD0 specifies the Baud rate |
| | | | of the device. |
| TXIR | O | — | Asynchronous transmit to IrDA |
| | | | transceiver |
| RXIR | I | ST | Asynchronous receive from IrDA |
| | | | transceiver |
| RESET | I | ST | Resets the Device |
| V_{SS} | — | P | Ground reference for logic and I/O Pins |
| EN | I | TTL | Device Enable. May be used in low power |
| | | | and sleep modes |
| TX | I | TTL | Asynchronous receive; from Host |
| | | | Controller UART |
| RX | O | — | Asynchronous transmit; to Host Controller |
| | | | UART |
| RI | O | — | Ring Indicator. The value on this pin is |
| | | | driven high. |
| DSR | O | — | Data Set Ready. Indicates that the host |
| | | | controller has completed reset. |
| DTR | I | TTL | Data Terminal Ready. The value on this |
| | | | pin is ignored. |
| CTS | O | — | Clear to Send. Indicates that the host |
| | | | controller is ready to receive data. |
| RTS | I | TTL | Request to Send. Indicates that a Host |
| | | | Controller is ready to receive, and that |
| | | | the host controller must prepare send |
| | | | data if available. |
| V_{DD} | — | P | Positive supply for logic and I/O pins |
| OSC2 | O | — | Oscillator crystal Output |
| OSC1/ | I | CMOS | Oscillator crystal input/external clock |
| CLKIN | | | source input |
| CD | O | — | Carrier Detect. Indicates that the host |
| | | | controller has established a valid IrDA |
| | | | link with a Primary Device. |
| BAUD1 | I | ST | BAUD1:BAUD0 specify the Baud rate of |
| | | | the device. |

TABLE 2
(DCE)

| PIN | PIN | BUFFER | |
|---|---|---|---|
| NAME | TYPE | TYPE | DESCRIPTION |
| BAUD0 | I | ST | BAUD1:BAUD0 specify the Baud rate |
| | | | of the device. |
| TXIR | O | — | Asynchronous transmit to IrDA |
| | | | transceiver |
| RXIR | I | ST | Asynchronous receive from IrDA |
| | | | transceiver |
| RESET | I | ST | Resets the Device |
| V_{SS} | — | P | Ground reference for logic and I/O Pins |
| EN | I | TTL | Device Enable. May be used in low power |
| | | | and sleep modes |
| TX | I | TTL | Asynchronous receive; from Host |
| | | | Controller UART |
| RX | O | — | Asynchronous transmit; to Host |
| | | | Controller UART |
| RI | I | TTL | Ring Indicator. The status of this bit is |
| | | | passed back to the IrDA Primary Device. |
| DSR | O | — | Data Set Ready. Indicates that the host |
| | | | controller has established a valid IrDA |
| | | | link with a Primary Device.⁽²⁾ |
| DTR | I | TTL | Data Terminal Ready. The status of this |
| | | | bit is passed back to the IrDA Primary |
| | | | Device. |
| CTS | O | — | Clear to Send. Indicates that the host |
| | | | controller is ready to receive data. |
| RTS | I | TTL | Request to Send. Indicates that a Host |
| | | | Controller is ready to receive, and that |
| | | | the host controller must prepare send |
| | | | data is available. |
| V_{DD} | — | P | Positive supply for logic and I/O pins |
| OSC2 | O | — | Oscillator crystal Output |
| OSC1/ | I | CMOS | Oscillator crystal input/external clock |
| CLKI | | | source input |
| N | | | |
| CD | I | ST | Carrier Detect. The status of this bit is |
| | | | passed back to the IrDA Primary Device. |
| BAUD1 | I | ST | BAUD1:BAUD0 specify the Baud rate of |
| | | | the device. |

Legend:
TTL = TTL compatible input
I = Input
P = Power
ST = Schmitt Trigger input with CMOS levels
O = Output
CMOS = CMOS compatible input

Each of the pins advantageously is adapted with circuitry, and/or a programmable device (e.g., microcontrollers, microprocessors, application specific integrated circuits (ASIC), programmable gate arrays (PGA) and other devices and/or combinations thereof) is programmed with firmware, to be dedicated to the functions as listed in Tables 1 and 2. Of course the exact form of the circuitry and/or firmware used to create such functionality and adapt such pins may vary depending upon the particular application involved. Without limitation as to the scope of the present invention, for the sake of clarity and convenience reference will be made herein to a firmware embodiment of the present invention.

### BRIEF DESCRIPTION OF THE DRAWINGS

Further objects and advantages of the present invention will become apparent upon reading the following detailed description and upon referring to the accompanying drawings in which:

FIGS. 1a and 1b are diagrams illustrating exemplary DTE and DCE embodiments, respectively, of an 18-pin microcontroller including a functional pathway configuration for the interface between the microcontroller and a system in which the microcontroller is embedded, in accordance with the present invention;

FIGS. 2a and 2b are diagrams illustrating exemplary DTE and DCE embodiments, respectively, of a 20-pin microcontroller including a functional pathway configuration for the interface between the microcontroller and a system in which the microcontroller is embedded, in accordance with the present invention;

FIGS. 3a and 3b are functional block diagrams illustrating exemplary embodiments of the 18-pin microcontroller illustrated in FIGS. 1a and 1b, respectively, and the 20-pin microcontroller illustrated in FIGS. 2a and 2b, respectively, as embedded within an exemplary system, in accordance with the present invention.

FIGS. 4a and 4b are block diagrams illustrating exemplary DTE and DCE systems, respectively, comprising an embedded microcontroller including a functional pathway configuration for the interface between the microcontroller and the system, in accordance with the present invention.

The present invention may be susceptible to various modifications and alternative forms. Specific embodiments of the present invention are shown by way of example in the drawings and are described herein in detail. It should be understood, however, that the description set forth herein of specific embodiments is not intended to limit the present invention to the particular forms disclosed. Rather, all modifications, alternatives, and equivalents falling within the spirit and scope of the invention as defined by the appended claims are intended to be covered.

### DETAILED DESCRIPTION OF SPECIFIC EMBODIMENTS

The description below illustrates embodiments of the present invention. For the sake of clarity, not all features of an actual implementation of the present invention are described in this specification. It should be appreciated that in connection with developing any actual embodiment of the present invention many application-specific decisions must be made to achieve specific goals, which may vary from one application to another. Further, it should be appreciated that any such development effort might be complex and time-consuming, but would still be routine for those of ordinary skill in the art having the benefit of this disclosure.

For the sake of clarity and convenience, aspects of the present invention are described in the context of various embodiments typically used in applications generally involving IR communications, examples of which are set forth herein. However, the present invention may also be useful in a wide variety of other wireless applications.

Also, although the present invention may be used with discrete components, microprocessors, microcontrollers, application specific integrated circuits (ASIC), programmable gate arrays (PGA) and other devices and/or combinations thereof, for the sake of clarity and convenience reference is made herein to microcontrollers. One of ordinary skill in the art of electronics would readily appreciate and be able to contemplate other and further applications of the present invention by having the benefit of this disclosure.

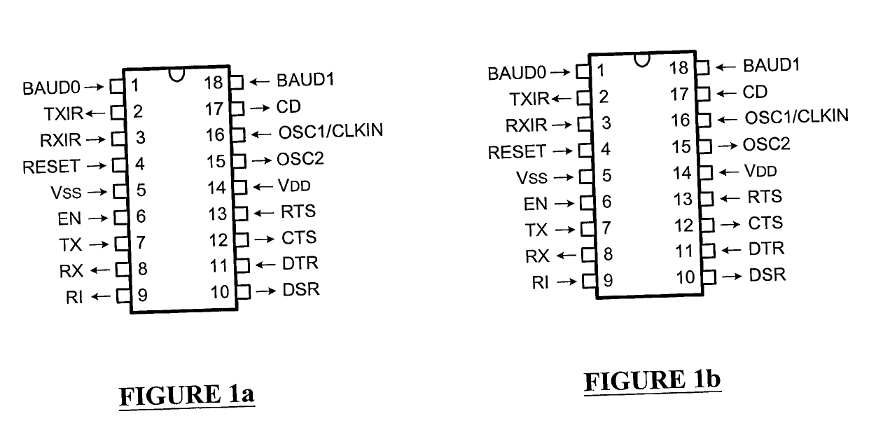

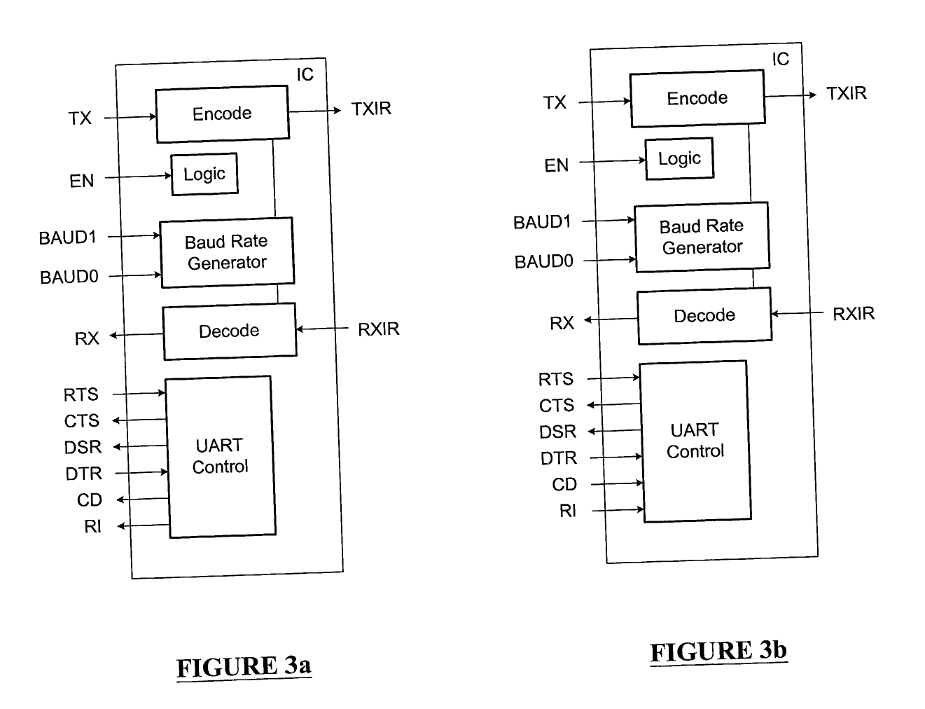

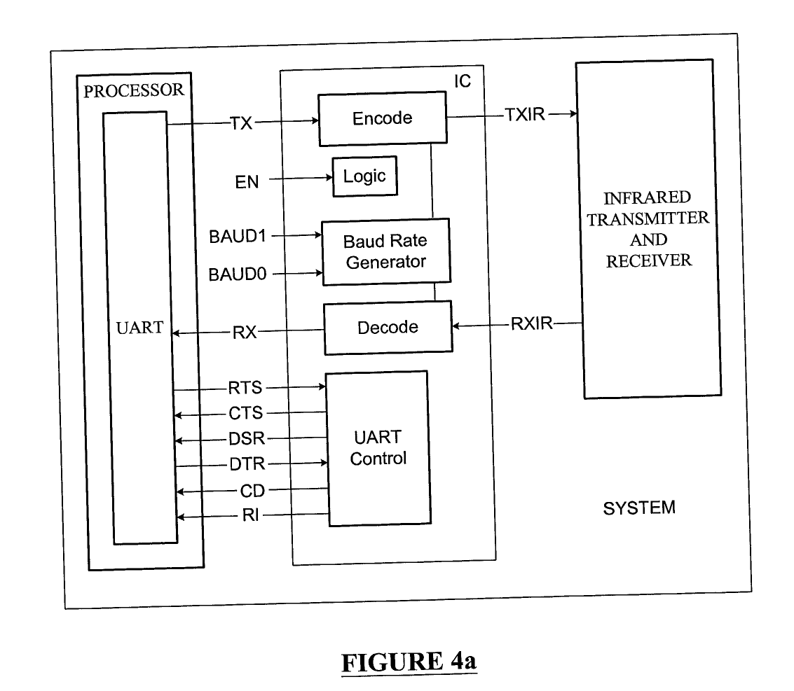

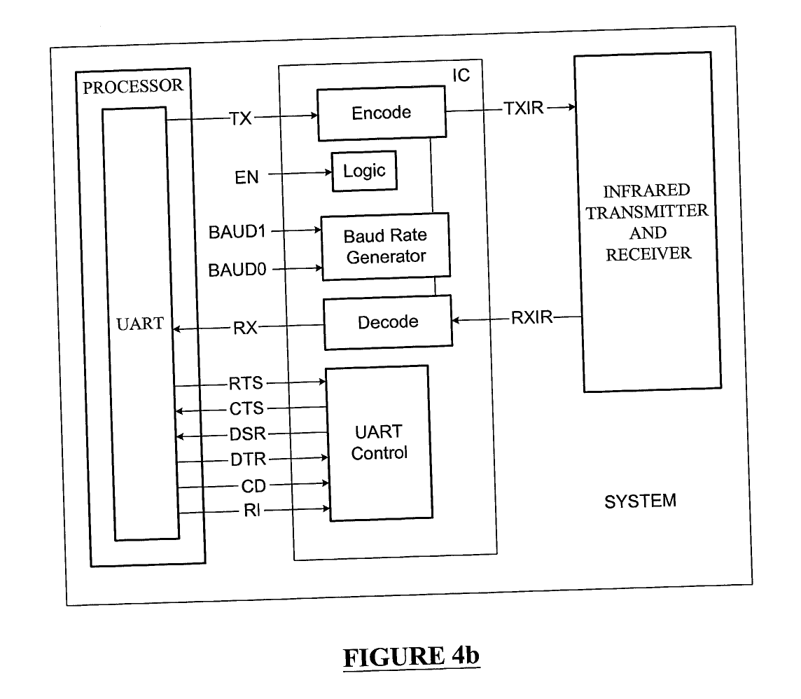

Turning now to the drawings, and by way of general illustration, as shown in FIGS. 1a and 1b, exemplary embodiments in accordance with the present invention comprise a plastic dual in-line package (PDIP) or ceramic dual in-line package (CERDIP) 18 pin microcontroller having functional pathway configurations for the interface between the microcontroller and a system (see FIGS. 4a and 4b) in which the microcontroller is embedded. Functional block diagrams of the 18 pin microcontroller are illustrated in FIGS. 3a and 3b.

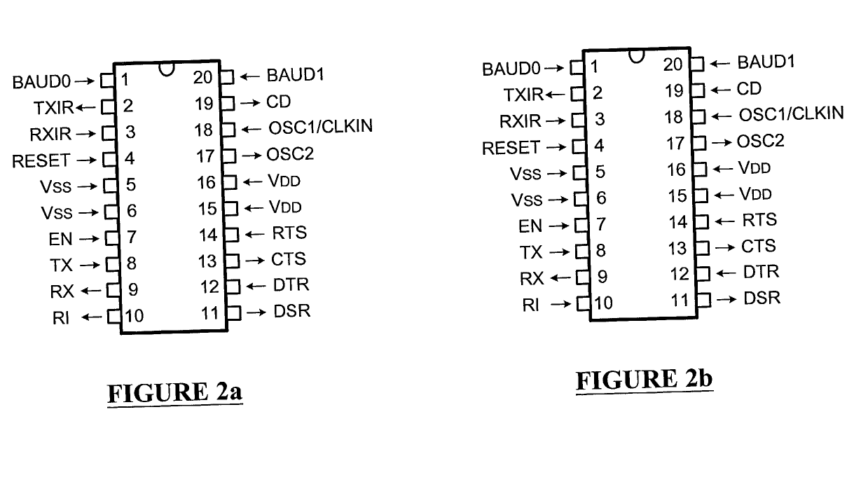

Referring to FIGS. 2a and 2b, exemplary embodiments in accordance with the present invention comprise a plastic dual in-line package (PDIP) or ceramic dual in-line package (CERDIP) 20 pin microcontroller having functional pathway configurations for the interface between the microcontroller and a system (see FIGS. 4a and 4b) in which the microcontroller is embedded. Functional block diagrams of the 20 pin microcontroller are illustrated in FIGS. 3a and 3b.

As depicted in FIGS. 1a to 4b, the microcontroller is in general functionally configured so as to advantageously increase the ability to simplify routing for system board design and microcontroller placement therein. Such advantage may prove beneficial in some cases, e.g., to an applications engineer in situations where partitioning of the printed circuit board in which the microcontroller is to be mounted would prove to be advantageous. In the embodiments shown, the locations of the signal pins demonstrate that the signal conductor layout may be accomplished on a single side of a printed circuit board (PCB) or printed wiring board (PWB). This advantageously simplifies fabrication and lowers overall costs to manufacture a product.

Referring to FIGS. 4a and 4b, depicted are partial schematic block diagrams of Data Terminal Equipment (DTE) and Data Communication Equipment (DCE) systems, respectively, adapted for infrared (IR) communications with another system (not shown) having similar IR communications capabilities. The system having infrared communications capabilities comprises a universal asynchronous receiver-transmitter (UART) in combination with a processor (e.g., microcontrollers, microprocessors, application specific integrated circuits (ASIC), programmable gate arrays (PGA) and other devices and/or combinations thereof), an infrared transmitter and receiver, and the present invention comprising functional pathways to a logic circuit, a baud rate generator, a UART control, an encode circuit and a decode circuit. The functional pathways, according to an exemplary embodiment of the invention, comprise an encode TX function input and TXIR output, a decode RXIR function input and RX function output, logic BAUD0 and BAUD1 function inputs, an EN logic function input, and UART function control and status signals RTS, CTS, DSR, DTR, CD and RI. Not illustrated but contemplated and within the scope of the present invention is a logic RESET function input, an OSC1/CLKIN function input, an OSC2 function output and power supply VDD and VSS function inputs (see FIGS. 1a, 1b, 2a and 2b).

The TX functional pathway is adapted for coupling to a serial data output of the UART. The TXIR functional pathway is adapted for coupling to an IR transmitter electrical input. The RX functional pathway is adapted for coupling to a serial data input of the UART. The RXIR functional pathway is adapted for coupling to an IR receiver electrical output. The IR receiver may have a logic level output or may only be an IR detector having a low level analog output. The BAUD1 and BAUD0 functional pathways are adapted for coupling to logic levels that define a hardware baud rate. The RESET functional pathway is adapted for coupling to a logic level for controlling a reset function of the logic circuits (e.g., microcontroller). The EN functional pathway (FIG. 1) may be adapted for coupling to a logic level for controlling an operation or sleep mode of the logic circuits for power reduction when not in use. The OSC1/CLKIN functional pathway is adapted for coupling to a system clock or one node of a frequency determining element such as a crystal. The OSC2 functional pathway is adapted for coupling to the other node of the frequency determining element or as an oscillator/clock output. The VDD and VSS functional pathways are adapted for coupling to power supply voltages required to operate the devices in the system.

The UART functional pathway control and status signals RTS, CTS, DSR, DTR, CD and RI are adapted for connection to a standard UART and may perform the following functions: RTS represents a “request to send” and indicates that a host controller is ready to receive or prepared to send data if available. CTS represents “clear to send” and indicates that the host controller is ready to receive data. DSR represents “data set ready” and indicates that the host controller has completed reset and is ready or the host controller has established a valid IrDA (infrared) link with a primary device. DTR represents “data terminal ready” and is either ignored or is a status that is passed to the IrDA primary device. CD represents “carrier detect” and indicates that the host controller has established a valid IrDA link with a primary device in the DTE embodiments. In the DCE embodiments, CD receives a carrier detect signal and passes detection of a carrier back to the IrDA primary device. RI represents “ring indicator” and is either ignored or the status is passed back to the primary IrDA primary device.

The present invention has been described in terms of exemplary embodiments. In accordance with the present invention, the parameters for a system may be varied, typically with a design engineer specifying and selecting them for the desired application. Further, it is contemplated that other embodiments, which may be devised readily by persons of ordinary skill in the art based on the teachings set forth herein, may be within the scope of the invention, which is defined by the appended claims. The present invention may be modified and practiced in different but equivalent manners that will be apparent to those skilled in the art having the benefit of the teachings set forth herein.

No limitations are intended to the details or construction or design shown herein, other than as described in the claims appended hereto. Thus, it should be clear that the specific embodiments disclosed above may be altered and modified, and that all such variations and modifications are within the spirit and scope of the present invention as set forth in the claims appended hereto.

What is claimed is:

1. An integrated circuit (IC) functional pathway configuration of connections, comprising: BAUD0, TXIR, RXIR, RESET, VSS, EN, TX, RX, RI, DSR, DTR, CTS, RTS, VDD, OSC2, OSC1/CLKIN, CD and BAUD1.

2. The IC functional pathway configuration according to claim 1, wherein the connections are arranged as follows:

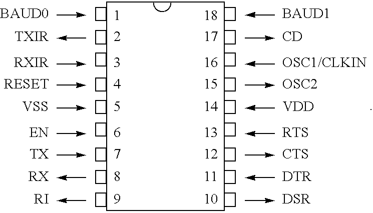

3. The IC functional pathway configuration according to claim 1, wherein the connections are arranged as follows:

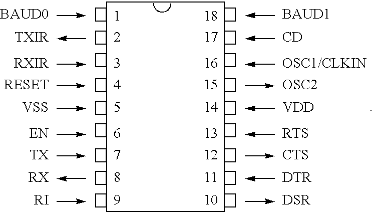

4. The IC functional pathway configuration according to claim 1, wherein the connections are arranged as follows:

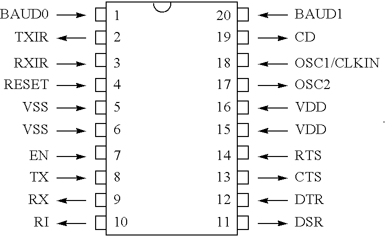

5. The IC functional pathway configuration according to claim 1, wherein the connections are arranged as follows:

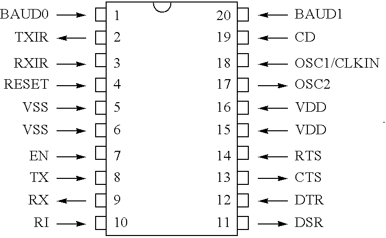

6. A functional pathway configuration for an encode/decode function, comprising:
an encode TX function input and an encode TXIR function output;
a decode RXIR function input and a decode RX function output;
a logic EN function input;
a logic RESET function input;
at least one logic BAUD function input; and
UART function inputs and outputs.

7. The functional pathway configuration according to claim 6, wherein the UART function inputs and outputs are selected from the group consisting of RTS, CTS, DSR, DTR, CD and RI.

8. A functional pathway configuration for an integrated circuit (IC) including encode/decode functions, logic, baud rate generator and UART control as follows:

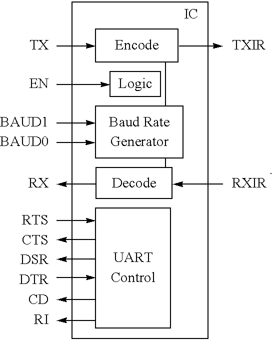

9. A functional pathway configuration for an integrated circuit (IC) including encode/decode functions, logic, baud rate generator and UART control as follows:

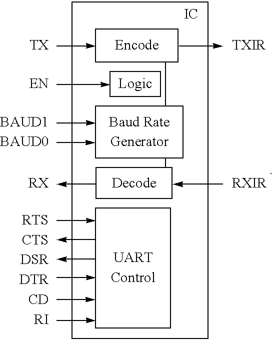

10. The functional pathway configuration according to claims 8 or 9, wherein pathway configuration function connections are arranged as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | EN |
| P7 | TX |
| P8 | RX |
| P9 | RI |
| P10 | DSR |
| P11 | DTR |
| P12 | CTS |
| P13 | RTS |
| P14 | VDD |
| P15 | OSC2 |
| P16 | OSC1/CLKIN |
| P17 | CD |
| P18 | BAUD1 |

11. The functional pathway configuration according to claims 8 or 9, wherein pathway configuration function connections are arranged as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | VSS |
| P7 | EN |
| P8 | TX |
| P9 | RX |
| P10 | RI |
| P11 | DSR |
| P12 | DTR |
| P13 | CTS |
| P14 | RTS |
| P15 | VDD |
| P16 | VDD |
| P17 | OSC2 |
| P18 | OSC1/CLKIN |
| P19 | CD |
| P20 | BAUD1 |

12. A functional pathway configuration for an encoder/decoder, comprising:
a first set of nine connections P1, P2 . . . P9, wherein each of the first set of nine connections has a dedicated function(s) as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | EN |
| P7 | TX |
| P8 | RX |
| P9 | RI |

a second set of nine connections P10, P9 . . . P18, wherein each of the second set of nine connections has a dedicated function(s) as follows:

| CONNECTION | FUNCTION(S) |
|---|---|
| P10 | DSR |
| P11 | DTR |
| P12 | CTS |
| P13 | RTS |
| P14 | VDD |
| P15 | OSC2 |
| P16 | OSC1/CLKIN |
| P17 | CD |
| P18 | BAUD1 |

wherein at least one of the sets is disposed on one side of an integrated circuit package.

13. A functional pathway configuration for an encoder/decoder, comprising:
a first set of ten connections P1, P2 . . . P10, wherein each of the first set of ten connections has a dedicated function(s) as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | VSS |
| P7 | EN |
| P8 | TX |
| P9 | RX |
| P10 | RI |

and;
a second set of ten connections P11, P9 . . . P20, wherein each of the second set of ten connections has a dedicated function(s) as follows:

| CONNECTION | FUNCTION(S) |
|---|---|
| P11 | DSR |
| P12 | DTR |
| P13 | CTS |
| P14 | RTS |
| P15 | VDD |
| P16 | VDD |
| P17 | OSC2 |
| P18 | OSC1/CLKIN |
| P19 | CD |
| P20 | BAUD1 |

wherein at least one of the sets is disposed on one side of an integrated circuit package.

14. A system having a functional pathway configuration for an interface between an integrated circuit (IC) and a system in which the IC is embedded, comprising: BAUD0, TXIR, RXIR, RESET, VSS, EN, TX, RX, RI, DSR, DTR, CTS, RTS, VDD, OSC2, OSC1/CLKIN, CD and BAUD1.

15. A functional pathway configuration for an interface between a system including a UART, an infrared transmitter and receiver, and an integrated circuit (IC) embedded in the system, comprising:

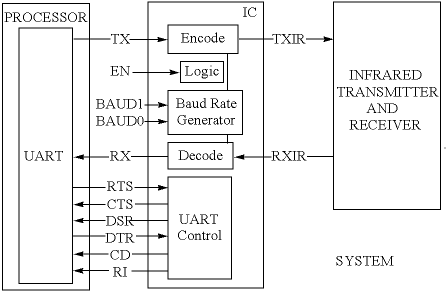

16. A functional pathway configuration for an interface between a system including a UART, an infrared transmitter and receiver, and an integrated circuit (IC) embedded in the system, comprising:

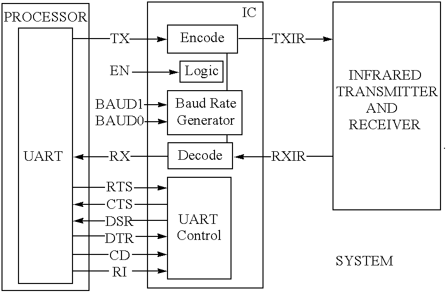

17. The functional pathway configuration according to claims 15 or 16, wherein:
a UART output interfaces with a function TX;
the UART input interfaces with a function RX;
an infrared transmitter input interfaces with a function TXIR; and
an infrared receiver output interfaces with a function RXIR.

18. The functional pathway configuration according to claims 15 or 16, wherein pathway configuration function connections are arranged as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | EN |
| P7 | TX |
| P8 | RX |
| P9 | RI |
| P10 | DSR |
| P11 | DTR |
| P12 | CTS |
| P13 | RTS |
| P14 | VDD |
| P15 | OSC2 |
| P16 | OSC1/CLKIN |
| P17 | CD |
| P18 | BAUD1 |

19. The functional pathway configuration according to claims 15 or 16, wherein pathway configuration function connections are arranged as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | VSS |
| P7 | EN |
| P8 | TX |
| P9 | RX |
| P10 | RI |
| P11 | DSR |
| P12 | DTR |
| P13 | CTS |
| P14 | RTS |
| P15 | VDD |
| P16 | VDD |
| P17 | OSC2 |
| P18 | OSC1/CLKIN |
| P19 | CD |
| P20 | BAUD1 |

20. The functional pathway configuration according to claims 15 or 16, further comprising:
a first set of nine connections P1, P2 . . . P9, wherein each of the first set of nine connections has a dedicated function(s) as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | EN |
| P7 | TX |
| P8 | RX |
| P9 | RI |

and;
a second set of nine connections P10, P9 . . . P18, wherein each of the second set of nine connections has a dedicated function(s) as follows:

| CONNECTION | FUNCTION(S) |
|---|---|
| P10 | DSR |
| P11 | DTR |
| P12 | CTS |
| P13 | RTS |
| P14 | VDD |
| P15 | OSC2 |
| P16 | OSC1/CLKIN |
| P17 | CD |
| P18 | BAUD1 |

wherein at least one of the sets is disposed on one side of an integrated circuit package.

21. The functional pathway configuration according to claims 15 or 16, further comprising:
a first set of ten connections P1, P2 . . . P10, wherein each of the first set of ten connections has a dedicated function(s) as follows:

| CONNECTION | FUNCTION(S) |
|---|---|
| P1 | BAUD0 |
| P2 | TXIR |
| P3 | RXIR |
| P4 | RESET |
| P5 | VSS |
| P6 | VSS |
| P7 | EN |
| P8 | TX |
| P9 | RX |
| P10 | RI |

and;
a second set of ten connections P11, P9 . . . P20, wherein each of the second set of ten connections has a dedicated function(s) as follows:

| CONNECTION | FUNCTION(S) |
|---|---|
| P11 | DSR |
| P12 | DTR |
| P13 | CTS |
| P14 | RTS |
| P15 | VDD |
| P16 | VDD |
| P17 | OSC2 |
| P18 | OSC1/CLKIN |
| P19 | CD |
| P20 | BAUD1 |

wherein at least one of the sets is disposed on one side of an integrated circuit package.

22. The functional pathway configuration according to claim 15, wherein the system is data terminal equipment (DTE).

23. The functional pathway configuration according to claim 16, wherein the system is data communication equipment (DCE).
